(19) United States
(12) Patent Application Publication
(10) Pub. No.: US 2012/0264362 A1
(43) Pub. Date: Oct. 18, 2012

(54) FUEL CELL AND CASE FOR FUEL CELL

(75) Inventors: Jong-Rock CHOI, Yongin-si (KR); Young-Seung NA, Yongin-si (KR); Jin S. HEO, Yongin-si (KR)

(73) Assignee: SAMSUNG SDI CO., LTD., Yongin-si (KR)

(21) Appl. No.: 13/246,520

(22) Filed: Sep. 27, 2011

Related U.S. Application Data
(60) Provisional application No. 61/476,626, filed on Apr. 18, 2011.

(51) Int. Cl. H05K 5/02

(52) U.S. Cl. 454/184

(57) ABSTRACT

A fuel cell case including a ventilating chamber disposed on an inside surface of the fuel cell case, a ventilator formed inside the ventilating chamber and an air inlet port formed on the outer surface of the ventilating chamber is disclosed. The ventilator may be formed protruding into the ventilating chamber. The fuel cell case may be formed such that ambient atmosphere is in fluid communication with the ventilating chamber, but water or other fluids outside the case do not enter the ventilator.

### CROSS-REFERENCE TO RELATED APPLICATIONS

This is a non-provisional application claiming priority to and the benefit of U.S. Provisional Application No. 61/476,626 filed Apr. 18, 2011, the disclosure of which is hereby incorporated by reference in its entirety.

### BACKGROUND

1. Field

The present disclosure relates to a fuel cell and a fuel battery case housing the fuel cell.

2. Description of the Related Technology

In general, a fuel battery case housing a fuel cell includes a ventilator for discharging a reaction gas or steam generated from the fuel cell and ventilating the interior of the fuel battery case. However, when the fuel battery case is exposed to rain, rainwater may flow into the receiving case through the ventilator. Accordingly, if the rainwater (or other fluid) flows into the fuel battery case, electric circuits inside the fuel battery case may be irreversibly damaged.

The above information disclosed in this Background section is only for enhancement of understanding and therefore it may contain information that does not form the prior art already known in this country to a person of ordinary skill in the art.

### SUMMARY OF CERTAIN INVENTIVE ASPECTS

In a first aspect, a fuel battery case for preventing a fluid from flowing into a fuel battery case even if the fuel battery case is exposed to a fluid such as rainwater is provided.

In another aspect, a fuel cell may include, for example, a fuel cell body, a case housing the fuel cell body, a ventilating plate connecting an inner wall surface of the case and forming a ventilating chamber inside the case, an air inlet port formed on an edge of the ventilating plate and allowing external air to flow therein, and a ventilating unit formed at the ventilating plate. In some embodiments the air inlet port allows fluid communication between the ventilating unit and ambient atmosphere. In some embodiments, when the fuel battery case is exposed to an environment in which a fluid may flow therein, the fluid does not flow inside the fuel battery case and thus damage to circuit elements inside the fuel battery case may be prevented.

In another aspect, a fuel cell case includes, for example, a ventilating chamber disposed on an inside surface of the fuel cell case, a ventilator formed inside the ventilating chamber, wherein the ventilator protrudes into the ventilating chamber and an air inlet port formed on the outer surface of the ventilating chamber.

In some embodiments, the ventilating chamber is positioned in an inside corner of the fuel cell case. In some embodiments, the ventilating chamber is formed by a ventilating plate. In some embodiments, a ventilating plate is formed with a first piece and a second piece connected at an angle. In some embodiments, the angle is approximately 90°. In some embodiments, the ventilator is formed on either the first piece or the second piece. In some embodiments, the ventilating plate includes a rounded shape connecting at least two inside surfaces of the fuel cell case. In some embodiments, the ventilator is formed in a conical frustum-shape. In some embodiments, the air inlet port includes a plurality of air inlet ports. In some embodiments, each of the plurality of air inlet ports includes a slit shape, which penetrates the inner wall surface of the fuel cell case. In some embodiments, each of the plurality of air inlet ports is formed protruding in an outer direction from the fuel cell case. In some embodiments, the fuel cell case is formed in a hexahedral shape. In some embodiments, when the first piece is positioned substantially normal to a direction of gravity, the second piece is positioned substantially parallel to the direction of gravity and the ventilator is positioned on the first piece, the ventilator includes a first height between the top of the ventilator and the first piece. In some embodiments, the air inlet port includes a second height between the first piece and air inlet port. In some embodiments, the first height is greater than the second height. In some embodiments, the fuel cell case further includes at least one protecting pad positioned on an exterior surface of the fuel cell case. In some embodiments, the ventilator is formed on the ventilating plate. In some embodiments, when the first piece is positioned substantially parallel to the direction of gravity and the second piece is positioned substantially parallel to the direction of gravity, the air inlet port includes a first air inlet port positioned above the ventilation chamber and a second air inlet port positioned below the ventilation chamber. In some embodiments, the first air inlet port includes a plurality of first air inlet ports. In some embodiments, the second air inlet port includes a plurality of second air inlet ports. In some embodiments, of the first and second plurality of air inlet ports is formed openings that each penetrate the inner wall surface of the fuel cell case. In some embodiments, each of the first and second plurality of air inlet ports is formed protruding in an outer direction from the fuel cell case. In some embodiments, the air inlet port includes a first air inlet port positioned above a top of the ventilator and a second air inlet port positioned below the top of the ventilator, the first air inlet port formed apart from the top of the ventilator. In some embodiments, when the first piece is positioned substantially normal to the direction of gravity and the second piece is positioned substantially parallel to the direction of gravity, the air inlet port includes a first air inlet port positioned above a top of the ventilator and a second air inlet port positioned below the top of the ventilator, the first air inlet port formed apart from the top of the ventilator.

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus, system or method according to some of the described embodiments can have several aspects, no single one of which necessarily is solely responsible for the desirable attributes of the apparatus, system or method. After considering this discussion, and particularly after reading the section entitled “Detailed Description of Certain Inventive Embodiments” one will understand how illustrated features serve to explain certain principles of the present disclosure.

FIG. 1 is a schematic perspective view of a fuel cell according to the first exemplary embodiment.

FIG. 2 is a partial sectional perspective view of a portion where a ventilating plate of the fuel battery case shown in FIG. 1 is installed.

FIG. 3 is a cross-sectional view of a protrusion of the fuel battery case shown in FIG. 1 protruded from a ventilating plate.

FIG. 4 is a partial perspective view of a portion where a ventilating plate is installed in a state in which the fuel battery case of FIG. 1 is slanted in a different direction.

FIG. 5 is a sectional perspective view of a ventilating plate of a fuel battery case according to the second exemplary embodiment.

FIG. 6 is a partial perspective view of a fuel battery case according to the third exemplary embodiment.

FIG. 7 is a cross-sectional view of an air inlet port of the fuel battery case of FIG. 6.

### DETAILED DESCRIPTION OF CERTAIN INVENTIVE EMBODIMENTS

A fuel battery case according to exemplary embodiments will now be described in detail with reference to the accompanying drawings. As those skilled in the art would realize, the described embodiments may be modified in various different ways, all without departing from the spirit or scope of the present disclosure. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Similarly, when it is described that an element is “coupled” to another element, the another element may be “directly coupled” to the other element or “electrically coupled” to the other element through a third element. Parts not related to the description are omitted for clarity. Hereinafter, like reference numerals refer to like elements. In the drawings, the thickness or size of layers are exaggerated for clarity and not necessarily drawn to scale. Certain embodiments will be described in more detail with reference to the accompanying drawings, so that a person having ordinary skill in the art can readily make and use aspects of the present disclosure.

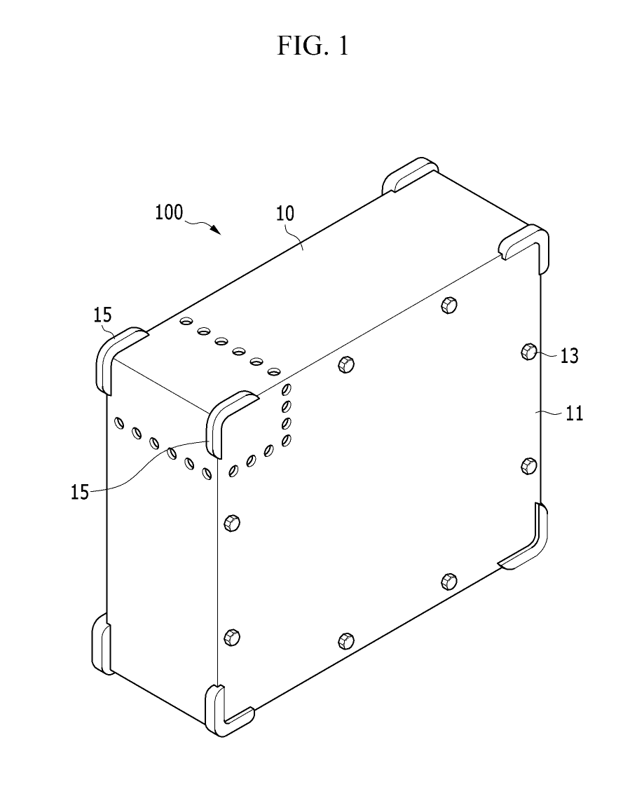

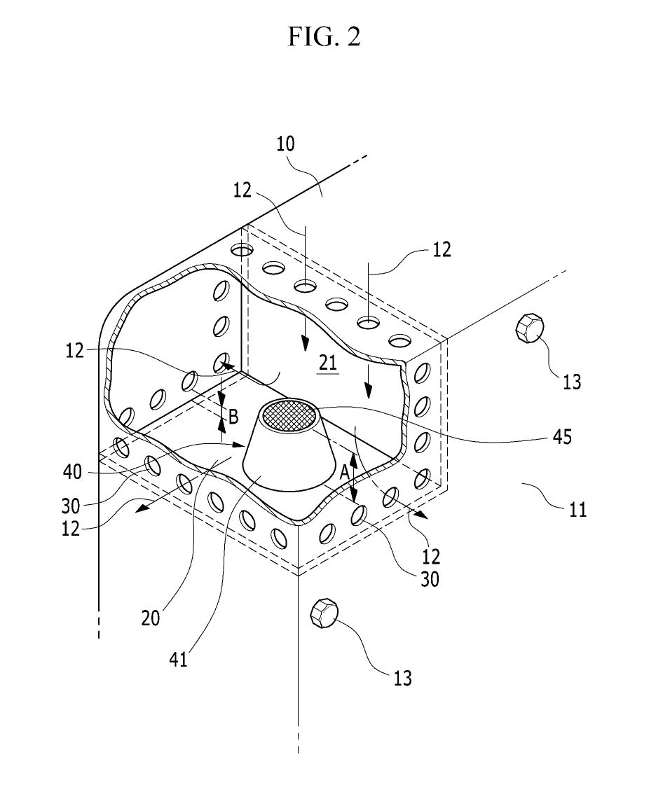

FIG. 1 is a schematic perspective view of a fuel cell according to the first exemplary embodiment, and FIG. 2 is a partial sectional perspective view of a portion where a ventilating plate of the fuel battery case shown in FIG. 1 is installed.

As shown in FIG. 1 and FIG. 2, a fuel cell 100 according to the first exemplary embodiment includes a ventilating plate 20 connecting between a first inner wall surface and a second inner wall surface of a case 10 housing a fuel cell body and forming a ventilating chamber 21. The fuel cell 100 also includes an air inlet port 30 formed on an edge of the ventilating plate 20 and configured to allow external air flow therein. The fuel cell 100 further includes a ventilating unit 40 formed on the ventilating plate 20, and configured to facilitate air circulation between the air inlet port 30 and the ventilating unit 40.

As shown in FIG. 1, the case 10 has an approximately hexahedral shape and houses the fuel cell body. In the present exemplary embodiment, the case 10 has the hexahedral shape, however the shape of the case is not limited thereto, and a portion of the side may include a rounded shape or may be a polyhedron besides the hexahedron. Hereafter, for convenience, it is prefiguratively described that the case 10 has the hexahedral shape.

The one side surface of the case 10 includes a cover 11. The cover 11 is configured to be attachable or detachable by using a bolt 13. Thus, the cover 11 serves to form the side of the case 10 after receiving the fuel cell body and other elements inside the case 10. A protecting pad 15 is configured to prevent an external impact from being transmitted to the case 10 when the case 10 is positioned in a horizontal or vertical direction. In the present exemplary embodiment, the protecting pad 15 may be formed of an elastic material, for example rubber, for impact absorption.

During operation of the fuel cell installed in the case 10, a reaction gas or steam may be generated by the electrochemical reaction between hydrogen and air. The ventilating chamber 21 is thus used for discharging the reaction gas or the steam and for allowing inflow of external air to ventilate the case 10. Thus, the ventilating plate 20 is installed inside the case 10 to form the ventilating chamber 21 near the top portion of the case 10.

As shown in FIG. 2, the ventilating plate 20 connects adjacent inner wall surfaces of the case 10 inside the corners of the case 10, and in detail, inside the corners of inclined surfaces where four surface of the case 10 meet, thereby forming the ventilating chamber 21 inside the case 10.

Herein, the inclined surfaces where four surface of the case 10 meet are not limited to the corners. That is, the inclined surfaces where four surface of the case 10 meet may be in rounded shape.

A ventilating chamber 21 may be formed inside the corners of all inclined surfaces of the case 10, or at least one of the corners of the inclined surfaces. In the present exemplary embodiment, the ventilating chamber 21 formed inside one inclined surface corner is exemplarily described.

The ventilating plate 20 positioned to form the ventilating chamber 21 is installed inside the case 10 with a bent portion, as shown in FIG. 2. The center portion of the length direction of the ventilating plate 20, as an example, is bent at about 90 degrees, and the edge thereof is fixed to the inner wall surface of the case 10. Accordingly, the ventilating chamber 21 formed by the ventilating plate 20 may be formed with a space of a hexahedral shape formed by four inner wall surfaces of the case and the surfaces of two ventilating plates.

The ventilating plate 20 and the case 10 are coupled to be attachable or detachable by bolt coupling or insert coupling. It is also possible for the case 10 to be integrally coupled to the case 10.

The air inlet port 30 in fluid communication with the ventilating chamber 21 is formed in the case 10. As shown in FIG. 2, the air inlet port 30 has a plurality of penetration holes formed along an edge of the ventilating plate 20. The air inlet port 30 may variously penetrate the case 10 with a circular, oval, polygonal or other appropriate shape. A plurality of air inlet ports 30 are arranged on the edge of the ventilating plate 20 in the case 10 in the present exemplary embodiment, however, in some embodiments only a single air inlet port 30 penetrates each inner wall surface of the case 10. When air inlet ports 30 penetrate each inner wall surface of the case 10, the air inlet ports 30 may penetrate with a slit shape. This makes it possible to sufficiently ventilate through the air inlet ports 30.

The air inlet ports 30 are formed on the receiving case 10, and thereby the fluid does not flow into the case 10 and the ventilation is smoothly realized in an environment in which a fluid such as rainwater may flow. This will be described in detail while explaining the ventilating unit 40 described later.

The ventilating unit 40 is formed protruding from the surface of the ventilating plate 20, and thereby the ventilating action of the steam or heated air generated by driving the fuel cell is executed.

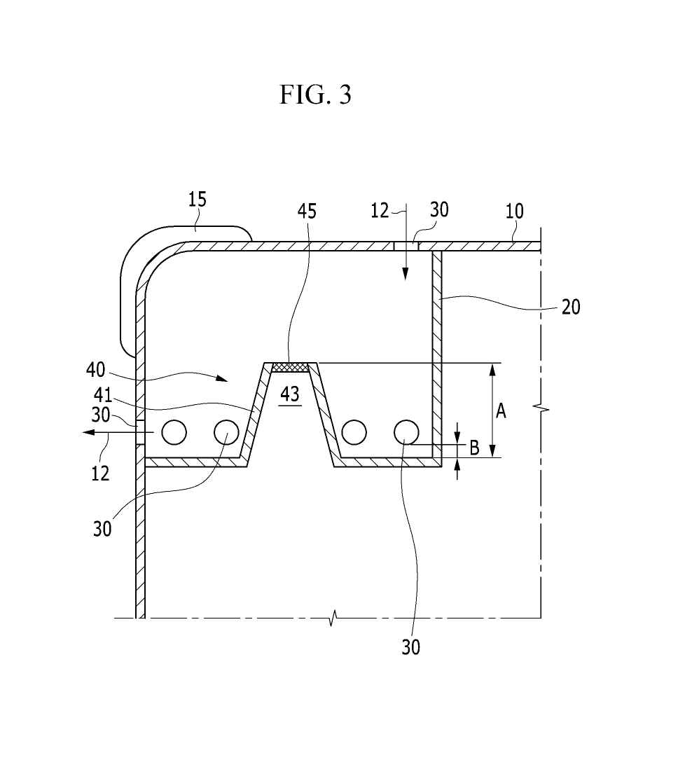

In detail, referring to the constitution of the ventilating unit 40, the ventilating unit 40 includes the protrusion 41 protruded from the surface of the ventilating plate 20 and a ventilator 43 (referring to FIG. 3) formed at the protruded front end of the protrusion 41.

The protrusion 41 may protrude with a conical shape from the surface of the ventilating plate 20. The protrusion 41 protrudes with the conical shape such that the fluid flowing in a direction 12 into the ventilating chamber 21 flows according to the surface of the rounded shape of the protrusion 41 and is guided to naturally flow outside the case 10 in the direction 12. Because the protrusion 41 protrudes from the ventilating plate 20, the fluid flowing from the air inlet port 30 of the case 10 in the direction 12 does not flow into the ventilator 43. In detail, the height A by which the protrusion 41 protrudes from the surface of the ventilating plate 20 is higher than the height B by which the air inlet port 30 is positioned from the surface of the ventilating plate 20. Accordingly, the level of the fluid 12 that flows from the air inlet port 30 of the case 10 is lower than the height A of the protrusion 41 such that the fluid 12 does not flow into the ventilator 43. Further, a filter member 45 is installed at the ventilator that is positioned at an end of the protrusion 41.

FIG. 3 is a cross-sectional view of a protrusion of the fuel battery case shown in FIG. 1 protruding from the ventilating plate 20. As shown in FIG. 3, the filter member 45 is fixed to the inner wall surface of the protrusion 41, and thereby impurities included in the external air flowing inside the case 10 are filtered. The filter member 45 may be formed as a porous filter with a plurality of through holes. In the state that the fuel cell 100 of the above-described embodiment is disposed in various directions, the fluid such as the rainwater does not flow inside the case 10.

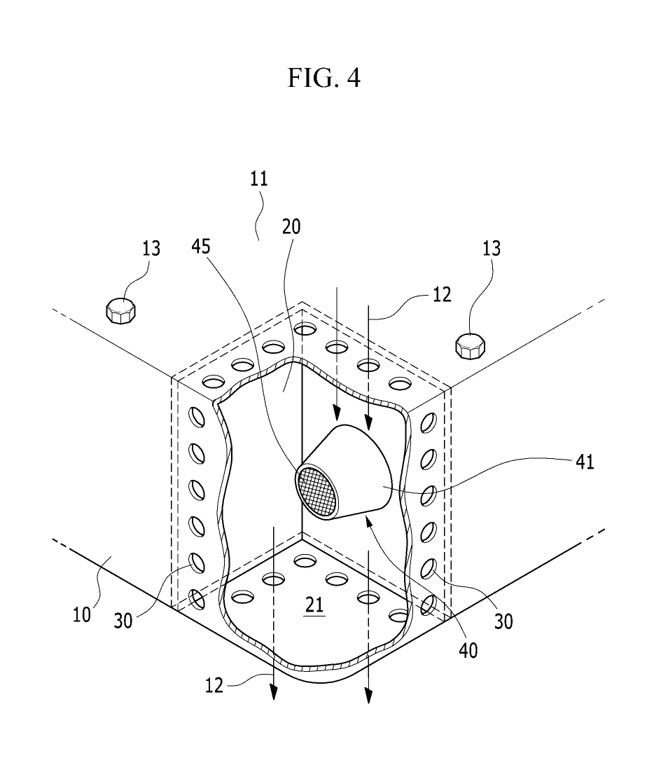

FIG. 4 is a partial perspective view of a portion where a ventilating plate is installed in a state that the fuel battery case of FIG. 1 is slanted in a different direction.

As shown in FIG. 4, in the state that the fuel battery case is disposed in the different direction from the installation direction of FIG. 1, a fluid flowing in the direction 12 into the air inlet port 30 formed at one side of the case 10 is discharged into the air inlet port 30 formed at the other side of the case 10 in the direction 12.

In detail, as shown in FIG. 4, the protrusion 41 protrudes from the ventilating plate 20, and although the fluid flows into the ventilating chamber 21 of the case 10 in the direction 12, the fluid is discharged at the air inlet port 30 under the protrusion 41 in the direction 12. Accordingly, the level of the fluid flowing into the ventilating chamber 21 is lower than the height of the protrusion 41, and thereby the fluid does not flow inside the case 10.

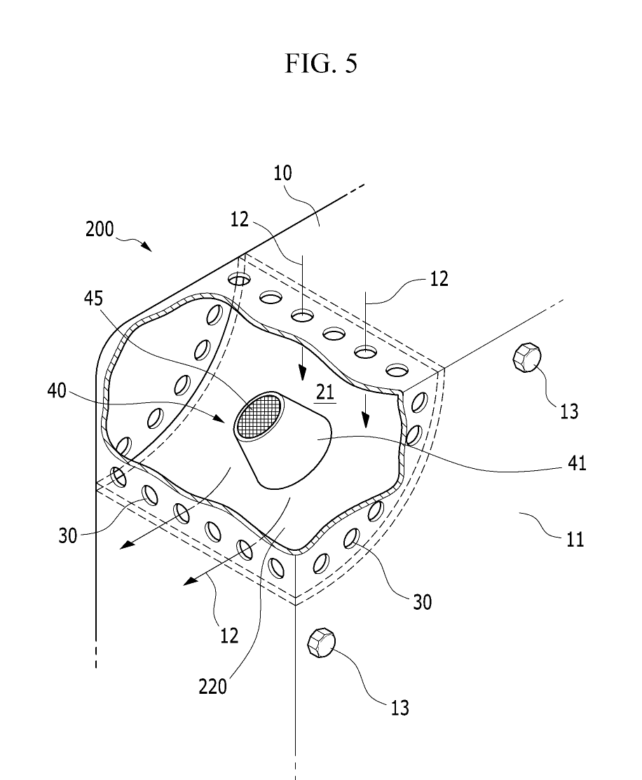

FIG. 5 is a sectional perspective view of a ventilating plate of a fuel battery case according to the second exemplary embodiment. The same reference numerals as those of FIG. 1 to FIG. 4 denote the same members. Thus, a detailed description of the same reference numerals will be omitted hereinafter. In some embodiments of FIG. 2, 4 or 5, the air inlet port 30 may include a first air inlet port 30 positioned above a top of the ventilator 43 and a second air inlet port 30 positioned below the top of the ventilator 43, the first air inlet port 30 formed apart from the top of the ventilator 43. In some embodiments, when the first piece of the ventilating plate 20 is positioned substantially normal to the direction of gravity and the second piece of the ventilating plate 20 is positioned substantially parallel to the direction of gravity, the air inlet port 30 includes a first air inlet port 30 positioned above a top of the ventilator 43 and a second air inlet port 30 positioned below the top of the ventilator 43, the first air inlet port 30 formed apart from the top of the ventilator 43.

As shown in FIG. 5, a ventilating plate 220 of a fuel battery case 200 according to the second exemplary embodiment has a rounded shape to connect between the inner wall surfaces of the case 10. Accordingly, the fluid 12 flowing through the air inlet port 30 may be discharged to the outside according to the surface of the rounded shape of the ventilating plate 220.

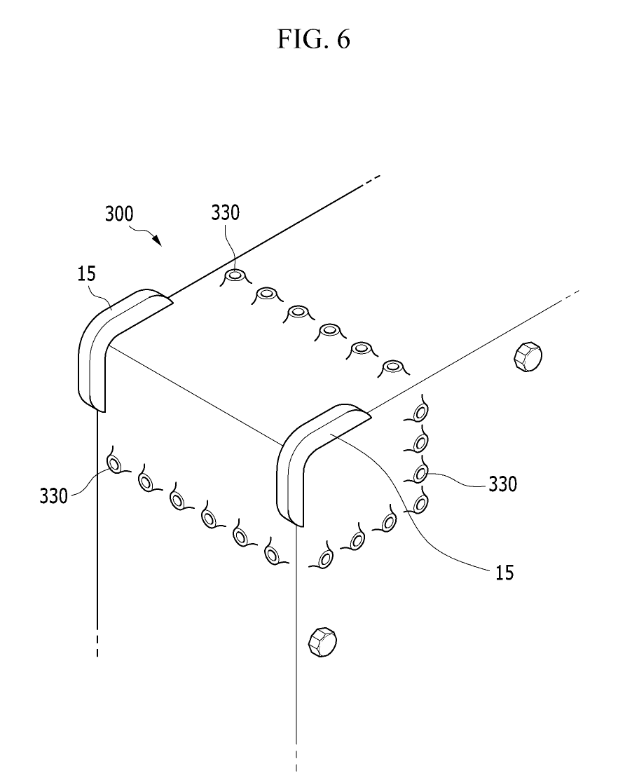

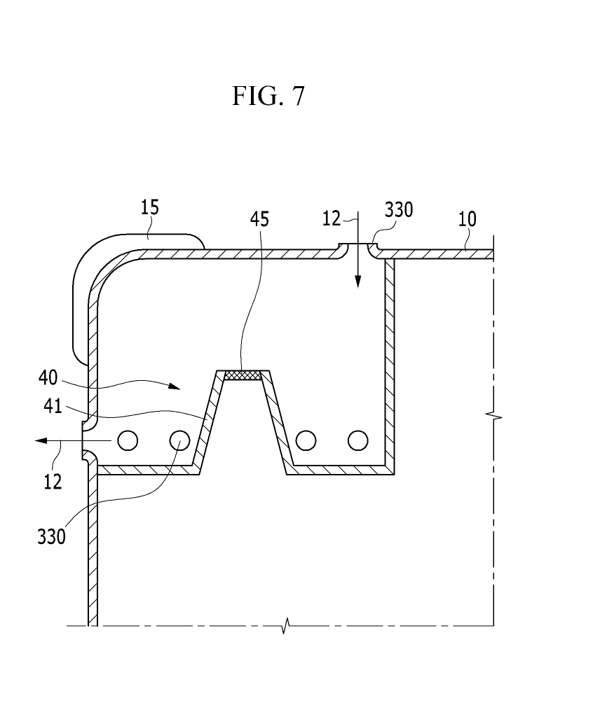

FIG. 6 is a partial perspective view of a fuel battery case according to the third exemplary embodiment, and FIG. 7 is a cross-sectional view of an air inlet port of the fuel battery case of FIG. 6. The same reference numerals as those of FIG. 1 to FIG. 5 denote the same members. Thus, a detailed description of the same reference numerals will be omitted hereinafter.

As shown in FIG. 6 and FIG. 7, a fuel cell 300 according to the third exemplary embodiment includes a plurality of air inlet ports 330 formed at the case. The edge of each air inlet port 330 is protruded in the outer direction of the case 10.

As described above, the edge of the air inlet port 330 of the third exemplary embodiment protrudes in the outer direction of the case 10 such that the fluid such as the rainwater does not easily flow into the air inlet port 330.

Accordingly, in the state that the air easily flows inside the case 10 through the air inlet port 330 such that the ventilating action is normal, the outer fluid does not flow in, thereby improving the stability of the fuel cell system.

While the present invention has been described in connection with certain exemplary embodiments, it will be appreciated by those skilled in the art that various modifications and changes may be made without departing from the scope of the present disclosure. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Thus, while the present disclosure has described certain exemplary embodiments, it is to be understood that the disclosure is not limited to the disclosed embodiments, but, on the contrary, is intended to cover various modifications and equivalent arrangements included within the spirit and scope of the appended claims, and equivalents thereof.

What is claimed is:

1. A fuel cell case, comprising:
a ventilating chamber disposed on an inside surface of the fuel cell case;
a ventilator formed inside the ventilating chamber, wherein the ventilator protrudes into the ventilating chamber; and
an air inlet port formed on the outer surface of the ventilating chamber.

2. The fuel cell case of claim 1, wherein the ventilating chamber is positioned in an inside corner of the fuel cell case.

3. The fuel cell case of claim 1, wherein the ventilating chamber is formed by a ventilating plate.

4. The fuel cell case of claim 3, wherein a ventilating plate is formed with a first piece and a second piece connected at an angle.

5. The fuel cell case of claim 4, wherein the angle is approximately 90°.

6. The fuel cell case of claim 4, wherein the ventilator is formed on either the first piece or the second piece.

7. The fuel cell case of claim 3, wherein the ventilating plate comprises a rounded shape connecting at least two inside surfaces of the fuel cell case.

8. The fuel cell case of claim 1, wherein the ventilator is formed in a conical frustum-shape.

9. The fuel cell case of claim 1, wherein the air inlet port comprises a plurality of air inlet ports.

10. The fuel cell case of claim 9, wherein each of the plurality of air inlet ports is formed having a slit shape, which penetrates the inner wall surface of the fuel cell case.

11. The fuel cell case of claim 9, wherein each of the plurality of air inlet ports is formed protruding in an outer direction from the fuel cell case.

12. The fuel cell case of claim 1, wherein the fuel cell case is formed in a hexahedral shape.

13. The fuel cell case of claim 3, wherein the air inlet port comprises a first air inlet port positioned above a top of the ventilator and a second air inlet port positioned below the top of the ventilator, and wherein the first air inlet port is formed apart from the top of the ventilator.

14. The fuel cell case of claim 13, wherein the first air inlet port comprises a plurality of first air inlet ports, and wherein the second air inlet port comprises a plurality of second air inlet ports.

15. The fuel cell case of claim 1 further comprising at least one protecting pad positioned on an exterior surface of the fuel cell case.

16. The fuel cell case of claim 7, wherein the ventilator is formed on the ventilating plate.

17. The fuel cell case of claim 6, wherein when the first piece is positioned substantially normal to the direction of gravity and the second piece is positioned substantially parallel to the direction of gravity, the air inlet port comprises a first air inlet port positioned above a top of the ventilator and a second air inlet port positioned below the top of the ventilator, and wherein the first air inlet port is formed apart from the top of the ventilator.

18. The fuel cell case of claim 17, wherein the first air inlet port comprises a plurality of first air inlet ports, and wherein the second air inlet port comprises a plurality of second air inlet ports.

19. The fuel cell case of claim 18, wherein each of the first and second plurality of air inlet ports is formed having openings that each penetrate the inner wall surface of the fuel cell case.

20. The fuel cell case of claim 18, wherein each of the first and second plurality of air inlet ports is formed protruding in an outer direction from the fuel cell case.
